(19) United States
(12) Patent Application Publication
(10) Pub. No.: US 2016/0096728 A1
(43) Pub. Date: Apr. 7, 2016

(54) MEMS Chip and Manufacturing Method Thereof

(71) Applicants: Yu-Fu Kang, Taipei (TW); Chiung-Cheng Lo, Zhunan Township (TW)

(72) Inventors: Yu-Fu Kang, Taipei (TW); Chiung-Cheng Lo, Zhunan Township (TW)

(73) Assignee: RICHTEK TECHNOLOGY CORPORATION, Chupei City (TW)

(21) Appl. No.: 14/966,562

(22) Filed: Dec. 11, 2015

Related U.S. Application Data
(62) Division of application No. 14/504,953, filed on Oct. 2, 2014.

(30) Foreign Application Priority Data
Jan. 27, 2014 (TW) 103102894

(51) Int. Cl. B81C 1/00

(52) U.S. Cl. CPC B81C 1/00285; B81C 2201/019; B81C 2201/013; B81C 2203/0792

(57) ABSTRACT

A MEMS chip includes a cap layer and a composite device layer. The cap layer includes a substrate. The substrate has a first region and a second region, wherein the first region includes plural first trenches and the second region has plural second trenches. The first region has a first etch pattern density and the second region has a second etch pattern density, wherein the first etch pattern density is higher than the second etch pattern density to form chambers of different pressures.

### CROSS REFERENCE

The present invention claims priority to TW 103102894, filed on Jan. 27, 2014.

### BACKGROUND OF THE INVENTION

1. Field of Invention

The present invention relates to a micro-electro-mechanical-system (MEMS) chip and a manufacturing method thereof; particularly, it relates to such MEMS chip and manufacturing method thereof wherein different regions of a cap wafer have different etch pattern densities, such that the MEMS chip has different chambers of different pressures.

2. Description of Related Art

In making a MEMS chip, it is often required to package a MEMS device such as a micro-acoustical sensor, gyro-sensor or accelerometer, etc. in a sealed space. Different types of MEMS devices require different operation pressures in the sealed space. For example, a gyro-sensor usually operates under 0.1 mbar to 10 mbar, whereas an accelerometer usually operates under 200 mbar to 1000 mbar. In a typical Wafer Level Packaging (WLP) method, only one operation pressure can be formed in a wafer in the manufacturing process. This constraint significantly limits the design flexibility; for example, it is very difficult to integrate different types of MEMS devices in one MEMS chip. For example, if it is desired to package a gyro-sensor and an accelerometer within one MEMS chip, two different sealed spaces having different operation pressures are required to be formed, one having a pressure from 0.1 mbar to 10 mbar and the other having a pressure from 200 mbar to 1000 mbar. However, the conventional WLP process can not manufacture such a MEMS chip.

To overcome such a drawback, U.S. Pat. No. 8,350,346 discloses a MEMS chip having different sealed spaces of different operation pressures. In this prior art, the cap wafer is etched by multiple etch steps to form trenches of different depths at different regions, such that two sealed chambers having different volumes are formed to provide different operation pressures. However, in such prior art, it is required to form trenches of different depths by multiple etching steps, which requires complicated etch control and the manufacturing variance makes it more difficult to maintain consistent high accuracy.

In view of the above, to overcome the drawbacks in the prior art, the present invention proposes a MEMS chip and a manufacturing method thereof wherein different regions of the cap wafer have different etch pattern densities, such that the MEMS chip has different chambers of different pressures.

### SUMMARY OF THE INVENTION

From one perspective, the present invention provides a manufacturing method of a MEMS chip, comprising the steps of: making a cap wafer, which includes the steps of: providing a first substrate; etching a first region of the first substrate to form a plurality of first trenches within the first region, the first region having a first etch pattern density, and concurrently etching a second region of the first substrate to form a plurality of second trenches within the second region, the second region having a second etch pattern density, wherein each of the first trenches and each of the second trenches have substantially a same depth and the first etch pattern density of the first region is higher than the second etch pattern density of the second region; making a composite device wafer, wherein the composite device wafer includes a second substrate, and a first MEMS device and a second MEMS device on or above the second substrate; and bonding the cap wafer and the composite device wafer such that, between the cap wafer and the composite device wafer, a first chamber and a second chamber are formed in correspondence to the locations of the first region and the second region, respectively, wherein the first chamber accommodates the first MEMS device and the second chamber accommodates the second MEMS device.

In one embodiment, the first chamber has a lower pressure than the second chamber.

In one embodiment, the first region has a first top-view area and the second region has a second top-view area, wherein the first top-view area is equal to or different from the second top-view area.

In one embodiment, one of the first trenches has a first top-view area and one of the second trenches has a second top-view area, wherein the first top-view area is equal to or different from the second top-view area.

In one embodiment, the step of making a cap wafer further includes the step of: depositing a gas-absorbing material or an gas-releasing material on the first trenches.

In one embodiment, the step of making a cap wafer further includes the step of: depositing a gas-absorbing material or an gas-releasing material on the second trenches.

In one embodiment, the step of making a composite device wafer further includes the steps of: providing the second substrate; forming the first MEMS device, the second MEMS device and a sacrificial layer surrounding the first MEMS device and the second MEMS device on or above the second substrate; forming a hard mask layer on or above the first MEMS device, the second MEMS device and the sacrificial layer; defining a pattern of the hard mask layer; and etching to remove the sacrificial layer through the pattern of the hard mask layer.

In one embodiment, the step of making a composite device wafer further includes the steps of: providing a complementary metal-oxide semiconductor (CMOS) wafer, wherein the CMOS wafer includes the second substrate and a microelectronic circuit on the second substrate; providing a MEMS wafer, wherein the MEMS wafer includes the first MEMS device and the second MEMS device; and bonding the CMOS wafer and the MEMS wafer.

In one embodiment, the manufacturing method of the MEMS chip further comprises: providing a plurality of conductive plugs between the second substrate and the MEMS wafer.

From another perspective, the present invention provides a MEMS chip, comprising: a cap layer, which includes a first substrate, wherein the first substrate has a first region and a second region, the first region having a plurality of first trenches formed therein, the second region having a plurality of second trenches formed therein, each of the first trenches and each of the second trenches having a same depth, a first etch pattern density of the first region being higher than a second etch pattern density of the second region; and a composite device layer, which includes a second substrate, and a first MEMS device and a second MEMS device on or above the second substrate; wherein the cap layer is bonded with the composite device layer such that, between the cap layer and the composite device layer, a first chamber and a second chamber are formed in correspondence to the locations of the first region and the second region, respectively, wherein the first chamber accommodates the first MEMS device and the second chamber accommodates the second MEMS device.

The objectives, technical details, features, and effects of the present invention will be better understood with regard to the detailed description of the embodiments below, with reference to the attached drawings.

### BRIEF DESCRIPTION OF THE DRAWINGS

FIGS. 1-4 are schematic cross sectional views illustrating several embodiments of the present invention.

FIG. 5 shows a top view of the first substrate according to an embodiment of the present invention.

FIG. 6 shows a top view of the first substrate according to another embodiment of the present invention.

FIG. 7 shows a schematic cross sectional view of an embodiment corresponding to FIG. 6 wherein the cap wafer (top) has been bonded to the composite device wafer (bottom).

FIG. 8 shows a top view of the first substrate according to yet another embodiment of the present invention.

FIG. 9 shows a schematic cross sectional view of an embodiment corresponding to FIG. 8 wherein the cap wafer (top) has been bonded to the composite device wafer (bottom).

FIG. 10 shows a schematic cross sectional view of an embodiment for making the cap wafer according to the present invention.

FIGS. 11-13 show schematic cross sectional views of a first embodiment for making the composite device wafer according to the present invention.

FIGS. 14-16 show schematic cross sectional views of a second embodiment for making the composite device wafer according to the present invention.

### DESCRIPTION OF THE PREFERRED EMBODIMENTS

The above and other technical details, features and effects of the present invention will be will be better understood with regard to the detailed description of the embodiments below, with reference to the drawings. The drawings as referred to throughout the description of the present invention are for illustration only, to show the interrelations between the layers, regions and/or components, but not drawn according to actual scale.

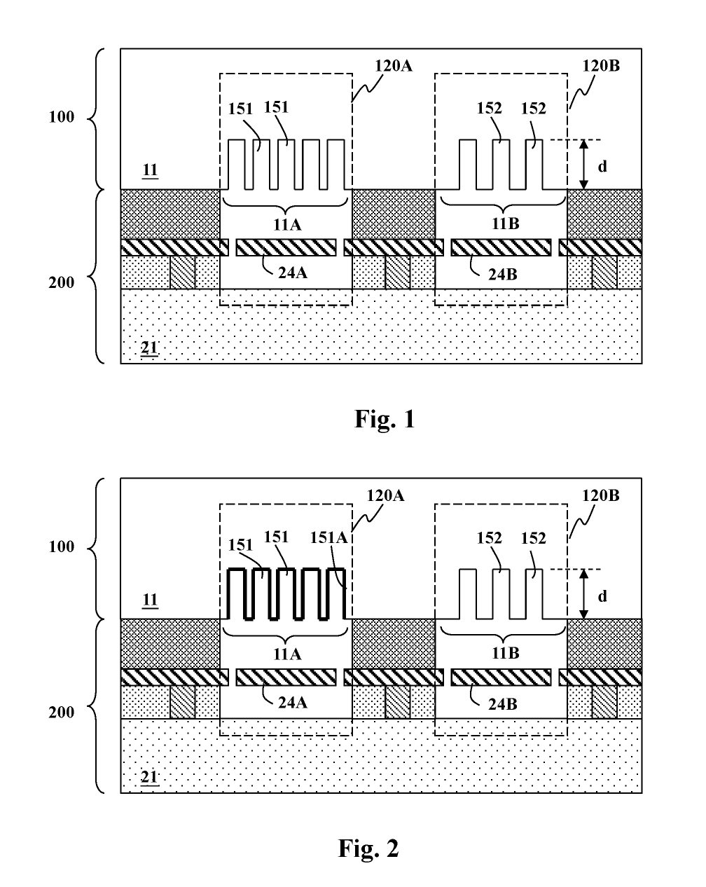

FIG. 1 shows a schematic cross sectional view of a MEMS chip according to an embodiment of the present invention. The MEMS chip 10 includes a cap wafer 100 and a composite device wafer 200 bonded to each other, wherein a first chamber 120A and a second chamber 120B having different operation pressures from each other are formed within the MEMS chip 10. (The cap wafer 100 and the composite device wafer 200 are bonded to each other as wafers and subsequently sliced to produce the MEMS chip 10. Therefore, from a perspective of a sliced chip, the cap wafer 100 and the composite device wafer 200 are no longer “wafers” in the original form of circular wafers. However, for the sake of understanding and as a customary term by one skilled in this art, the cap wafer 100 and the composite device wafer 200 are still referred to as “wafers”. From the perspective of a sliced chip, the cap wafer 100 and the composite device wafer 200 can also be referred to as a “cap layer” and a “composite device layer”, respectively.) The cap wafer 100 and the composite device wafer 200 can be bonded to each other via any known bonding process. In one embodiment, a bonding layer can be provided between the cap wafer 100 and the composite device wafer 200; the bonding layer for example can be, but not limited to, a glass frit material or a solder material. For example, the bonding layer can be made of a material suitable for soldering, including for example but not limited to: metal, aluminum-silicon alloy, silicon-gold alloy, tin-silver alloy, gold-germanium alloy, gold-tin alloy, or lead-tin alloy.

The cap wafer 100 includes a first substrate 11 (e.g., a silicon substrate) having a first region 11A and a second region 11B. The first region 11A has plural first trenches 151 and the second region 11B has plural second trenches 152. The first trenches 151 and the second trenches 152 have substantially the same depth d (“substantially” means that there may be non-uniformity in the manufacturing process to cause minor deviations of the depth, which are ignorable), but the first region 11A has a first etch pattern density which is relatively higher while the second region 11B has a second etch pattern density which is relatively lower. The term “etch pattern density” used herein is defined by (a total of top-view areas of the etched regions) divided by (the entire top-view area). The composite device layer 200 includes a second substrate 21, and a first MEMS device 24A and a second MEMS device 24B on or above the second substrate 21. The first MEMS device 24A and the second MEMS device 24B are located within the first chamber 120A and the second chamber 120B, respectively. The composite device layer 200 can further comprise, for example but not limited to, a microelectronic circuit such as a complementary metal-oxide-semiconductor (CMOS) transistor circuit or a bipolar junction transistor (BJT) circuit. Because the first trenches 151 and the second trenches 152 have the same depth d and only the etch pattern densities of the first region 11A and the second region 11B are different from each other, the manufacturing process of such a MEMS chip 10 is therefore much easier. It is simply required to define different patterns on the different regions by one same mask.

According to the ideal gas equation:

P=nRT/V,

where n denotes the gas number in the chamber (the unit is mole); P denotes the pressure in the chamber; V denotes the gas volume in the chamber; R denotes the ideal gas constant 1.987 cal/mol k; and T denotes the absolute temperature (the unit is K), it can be known that: if the absolute temperature is a constant, the pressure in the chamber can be determined according to the gas number n and the gas volume V. That is, the pressure P increases as the gas number n increases, while the pressure P decreases as the gas volume V increases. In the embodiment shown in FIG. 1, because the etch pattern densities of the first region 11A and the second region 11B are different from each other, the volumes of the first chamber 120 A and the second chamber 120B are different from each other; the volume of the second chamber 120B is smaller, so the pressure in the second chamber 120B is higher.

Please refer to FIG. 2, which shows a schematic cross sectional view of a MEMS chip according to another embodiment of the present invention. In this embodiment, a gas-absorbing material 151A which can absorb gas particles, such as a getter material, can be deposited on the first trenches 151 (completely or partially) to further adjust the pressure in the first chamber 120A. The gas-absorbing material 151A can absorb gas particles to decrease the gas number (i.e., n in the ideal gas equation) in the first chamber 120A, thereby further reducing the pressure.

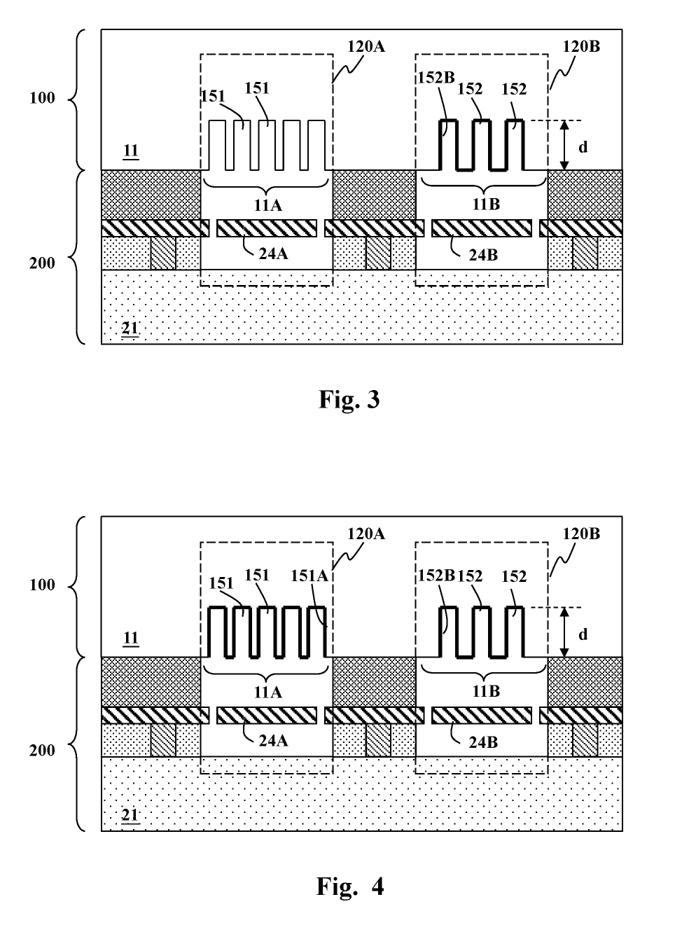

Please refer to FIG. 3, which shows a schematic cross sectional view of a MEMS chip according to yet another embodiment of the present invention. In this embodiment, a gas-releasing material 152B such as an outgas material can be deposited on the second trenches 152 (completely or partially) to further adjust the pressure in the second chamber 120B. The gas-releasing material can release gas particles to increase the gas number (i.e., n in the ideal gas equation) in the second chamber 120B, thereby further increasing the pressure.

The embodiments shown in FIGS. 2-3 can be combined to become still another embodiment as shown in FIG. 4. That is, not only a gas-absorbing material 151A is deposited on the first trenches 151 (completely or partially) but also a gas-releasing material 152B is deposited on the second trenches 152 (completely or partially), as shown in FIG. 4. Certainly, the present invention is not limited to depositing the gas-absorbing material 151A on the first trenches 151 to reduce the pressure, and/or depositing the outgas material 152B on the second trenches 152 to increase the pressure. It is also practicable and within the scope of the present invention to deposit the outgas material on the first trenches 151 to increase the pressure, and/or deposit the gas-absorbing material on the second trenches 152 to reduce the pressure.

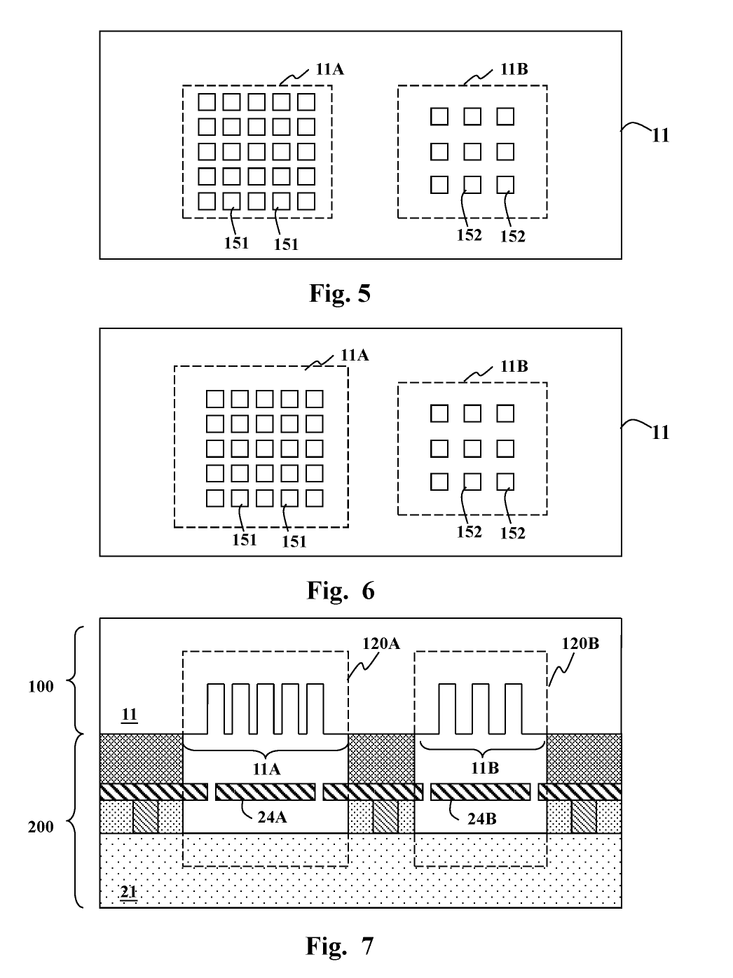

In the above-mentioned embodiments, preferably, the top-view area of the first region 11A and the top-view area of the second region 11B are substantially the same, as shown in FIG. 5. However, the present invention is not limited to such an example illustrated in FIG. 5. In another embodiment, the top-view area of the first region 11A and the top-view area of the second region 11B can be different from each other. For example, as shown in FIGS. 6-7, a first top-view area of the first region 11A can be larger than a second top-view area of the second region 11B, so that the pressure in the first chamber 120A is even lower than the embodiment of FIG. 5.

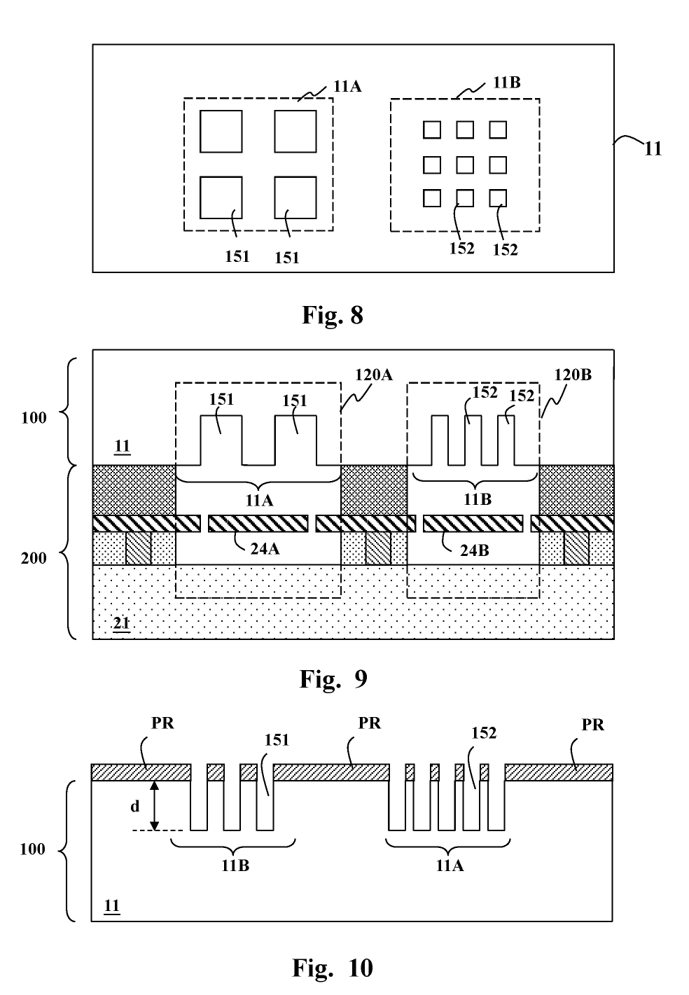

In the above-mentioned embodiments, preferably, the top-view area of each first trench 151 and the top-view area of each second trench 152 are substantially the same, as shown in FIG. 5. However, the present invention is not limited to such an example illustrated in FIG. 5. In another embodiment, the top-view area of each first trench 151 and the top-view area of each second trench 152 can be different from each other. For example, as shown in FIGS. 8-9, a first top-view area of each first trench 151 can be larger than a second top-view area of each second trench 152, so that the pressure in the first chamber 120A is even lower than the embodiment of FIG. 5.

In addition, the top-view areas of the trenches within the same region are not necessarily the same as one another.

According to the present invention, there are various methods to make and bond the cap wafer 100 and the composite device wafer 200. Please refer to FIG. 10, which shows a schematic cross sectional view of an embodiment for making the cap wafer according to the present invention. First, a first substrate 11, e.g. silicon substrate, is provided, and next a photoresist layer PR is deposited on the first substrate 11. Next, the photoresist layer PR is patterned by a lithography step. Next, the first substrate 11 is etched according to the desired pattern. Next, the photoresist layer PR is removed, and the cap wafer 100 having the desired trenches is obtained.

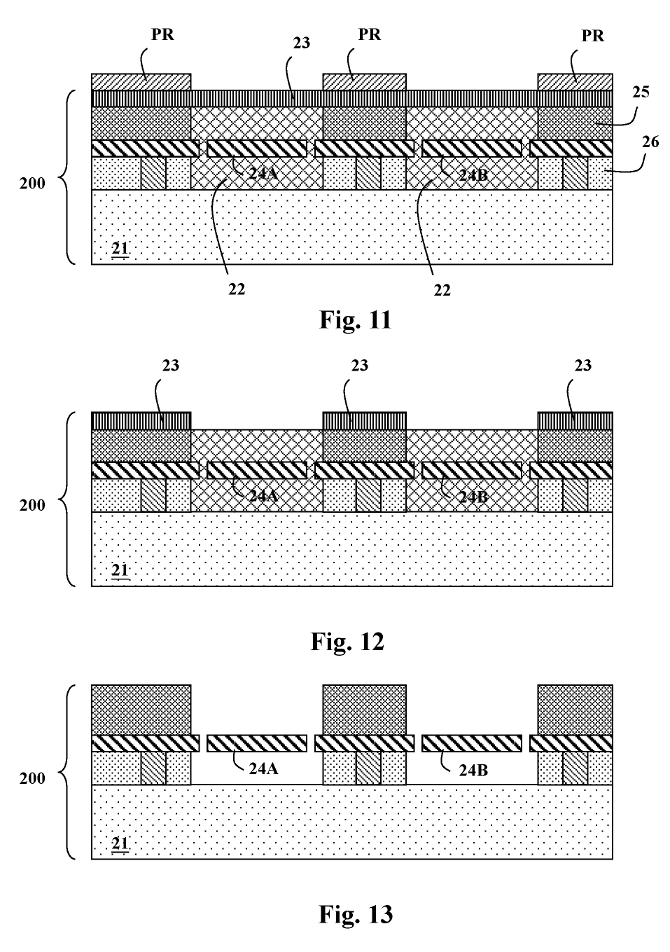

FIGS. 11-13 show schematic cross sectional views of a first embodiment for making the composite device wafer according to the present invention. First, a second substrate 21, e.g. silicon substrate, is provided, and next the desired patterns of multiple layers are manufactured on the second substrate 21 via a standard CMOS process. One of the layers is a sacrificial layer 22 surrounding the first MEMS device 24A and the second MEMS device 24B. A hard mask layer 23 can be included in the structure, located on or above the sacrificial layer 22. The material of the sacrificial layer 22 is different from the materials of the other parts of the structure (the first MEMS device 24A, the second MEMS device 24B, the material layer 25 and the material layer 26) surrounding the sacrificial layer 22. An appropriate etchant is provided to etch the sacrificial layer 22 and such appropriate etchant should have an appropriate etch selectivity to the above-mentioned surrounding parts (the first MEMS device 24A, the second MEMS device 24B, the material layer 25 and the material layer 26). Next, a photoresist layer PR is coated and patterned by a lithography step (as shown in FIG. 11). Next, the hard mask layer 23 is etched according to the desired pattern, and the remaining photoresist layer PR can be kept or removed (as shown in FIG. 12). Next, the sacrificial layer 22 is removed by etching, and the desired composite device wafer 200 is obtained (as shown in FIG. 13). The hard mask layer 23 can be reserved or removed depending on the design of the MEMS chip.

In the embodiments shown in FIGS. 11-13, the sacrificial layer 22 can be made of a material such as an oxide or a porous material. The first MEMS device 24A, the second MEMS device 24B, the material layer 25 and the material layer 26 can be made of a material such as metal or silicon. The hard mask layer 23 can be made of a material such as silicon nitride. The above-mentioned materials are for illustrative purpose only, but not for limiting the scope of the present invention.

In another embodiment, the material of the sacrificial layer 22 can simply be different from the materials of the first MEMS device 24A and the second MEMS device 24B, but is not necessarily different from the materials of the material layer 25 and the material layer 26. The sacrificial layer 22 is etched by an anisotropic etch method according to the pattern defined by the hard mask layer 23. Thus, the composite device wafer 200 as shown in FIG. 13 can also be obtained.

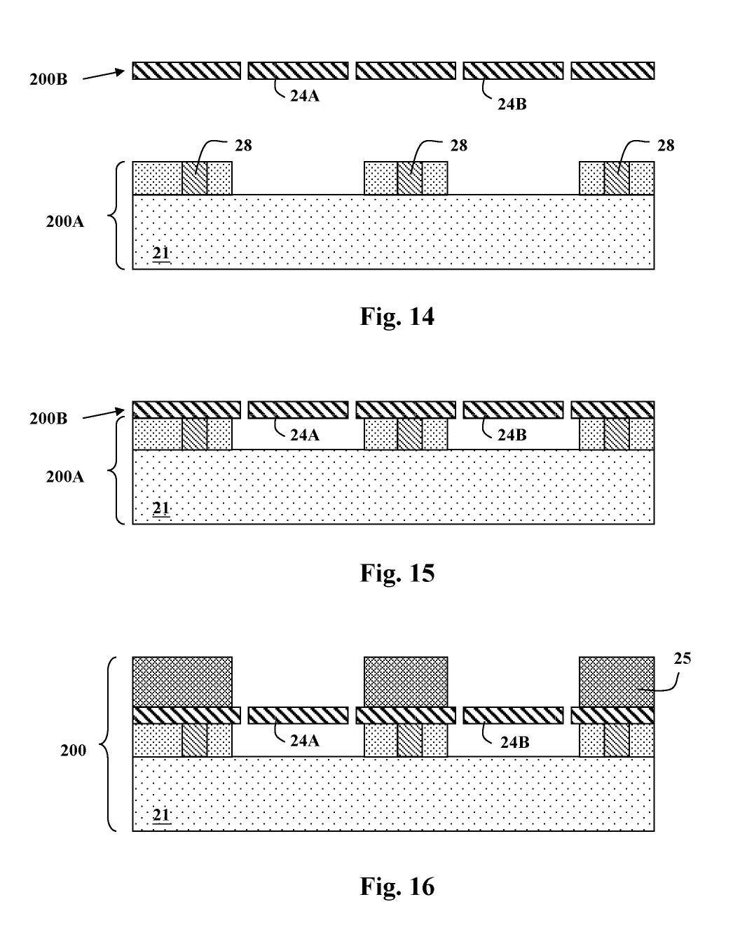

FIGS. 14-16 show schematic cross sectional views of a second embodiment for making the composite device wafer according to the present invention. In this embodiment, the composite device wafer 200 is formed by bonding a CMOS wafer 200A to a MEMS wafer 200B (as shown in FIGS. 14-15). In the MEMS wafer 200B, the structure and layout of the first MEMS device 24A and the second MEMS device 24B have already been defined and formed. The CMOS wafer 200A includes a second substrate 21 (e.g., silicon substrate) and a microelectronic circuit (not shown), manufactured by a standard CMOS process. In this embodiment, because it is required to electronically connect the microelectronic circuit of the CMOS wafer 200A to the first MEMS device 24A and the second MEMS device 24B of the MEMS wafer 200B, plural conductive plugs 28 are preferably provided. Next, the CMOS wafer 200A is bonded to the MEMS wafer 200B by providing a conducting adhesive in between, or by providing any adhesive which does not affect the conduction of the conductive plugs 28 at their locations, to obtain a composite device wafer 200. In this embodiment, the material layer 25 can be an adhesive layer provided for bonding the cap wafer 100.

After the cap wafer 100 and the composite device wafer 200 are bonded, in one embodiment, it is preferred to reduce the thickness of the first substrate 11 or the second substrate 21, or both, by grinding.

The present invention possesses the following feature and advantage: simply by designing the pattern densities of the first chamber 120A and the second chamber 120B, these chambers can have different pressures from each other by the same etching step.

It should be noted that the present invention is not limited to the aforesaid sequence of the steps; while the steps are described in a certain order, the sequence of the steps can be changed in other embodiments, and non-dependent steps can be implemented in parallel.

The present invention has been described in considerable detail with reference to certain preferred embodiments thereof. It should be understood that the description is for illustrative purpose, not for limiting the scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. In view of the foregoing, the spirit of the present invention should cover all such and other modifications and variations, which should be interpreted to fall within the scope of the following claims and their equivalents.

1. A manufacturing method of a micro-electro-mechanical-system (MEMS) chip, comprising the steps of:
making a cap wafer, which includes the steps of:
providing a first substrate; and
etching a first region of the first substrate to form a plurality of first trenches within the first region, the first region having a first etch pattern density, and concurrently etching a second region of the first substrate to form a plurality of second trenches within the second region, the second region having a second etch pattern density, wherein each of the first trenches and each of the second trenches have substantially a same depth and the first etch pattern density of the first region is higher than the second etch pattern density of the second region;
making a composite device wafer, wherein the composite device wafer includes a second substrate, and a first MEMS device and a second MEMS device on or above the second substrate; and
bonding the cap wafer and the composite device wafer such that, between the cap wafer and the composite device wafer, a first chamber and a second chamber are formed in correspondence to the locations of the first region and the second region, respectively, wherein the first chamber accommodates the first MEMS device and the second chamber accommodates the second MEMS device.

2. The manufacturing method of the MEMS chip of claim 1, wherein the first chamber has a lower pressure than the second chamber.

3. The manufacturing method of the MEMS chip of claim 1, wherein the first region has a first top-view area and the second region has a second top-view area, and wherein the first top-view area is equal to or different from the second top-view area.

4. The manufacturing method of the MEMS chip of claim 1, wherein one of the first trenches has a first top-view area and one of the second trenches has a second top-view area, and wherein the first top-view area is equal to or different from the second top-view area.

5. The manufacturing method of the MEMS chip of claim 1, wherein the step of making the cap wafer further includes the step of: depositing a gas-absorbing material or an outgas material on the first trenches.

6. The manufacturing method of the MEMS chip of claim 1, wherein the step of making the cap wafer further includes the step of: depositing a gas-absorbing material or an outgas material on the second trenches.

7. The manufacturing method of the MEMS chip of claim 1, wherein the step of making a composite device wafer further includes the steps of:
providing the second substrate;
forming the first MEMS device, the second MEMS device, and a sacrificial layer surrounding the first MEMS device and the second MEMS device on or above the second substrate;
forming a hard mask layer on or above the first MEMS device, the second MEMS device and the sacrificial layer;
defining a pattern of the hard mask layer; and
etching to remove the sacrificial layer through the pattern of hard mask layer.

8. The manufacturing method of the MEMS chip of claim 1, wherein the step of making a composite device wafer further includes the steps of:
providing a complementary metal-oxide semiconductor (CMOS) wafer, wherein the CMOS wafer includes the second substrate and a microelectronic circuit on the second substrate;
providing a MEMS wafer, wherein the MEMS wafer includes the first MEMS device and the second MEMS device; and
bonding the CMOS wafer and the MEMS wafer.

9. The manufacturing method of the MEMS chip of claim 8, further comprising: providing a plurality of conductive plugs between the second substrate and the MEMS wafer.

10.-15. (canceled)
